(19) United States
(12) Patent Application Publication
(10) Pub. No.: US 2025/0329568 A1
(43) Pub. Date: Oct. 23, 2025

(54) SYSTEM TO ASSIST VACUUM CHUCKING OF A SUBSTRATE

(71) Applicant: Applied Materials, Inc., Santa Clara, CA (US)

(72) Inventors: Preston Fung, Daly City, CA (US); Benjamin Michael Johnston, Los Gatos, CA (US); Rudolf Christian Brunner, Menlo Park, CA (US)

(21) Appl. No.: 18/643,079

(22) Filed: Apr. 23, 2024

(51) Int. Cl. H01L 21/683; B25B 11/00

(52) U.S. Cl. CPC H01L 21/6838; B25B 11/005

(57) ABSTRACT

A system is disclosed, including a vacuum a chuck configured to secure a substrate. The system further includes a substrate flattening unit configured to apply a downward force to a top surface of the substrate to flatten the substrate on the vacuum chuck. The system further includes one or more sealing members configured to form a vacuum seal between the vacuum chuck and the substrate proximate to one or more peripheral edges of the substrate when the substrate is flattened by the substrate flattening unit.

### TECHNICAL FIELD

The present disclosure generally relates to the field of semiconductor device manufacturing and more particularly to systems, methods, and apparatuses for securing a substrate on a vacuum chuck.

### BACKGROUND

Due to an ever-increasing demand for miniaturized electronic devices and components, integrated circuits have evolved into complex 2D, 2.5D, and 3D devices that can include millions of transistors, capacitors, and resistors on a single chip. The evolution of chip design has resulted in greater circuit density to improve the processing capability and speed of integrated circuits. The demand for faster processing capabilities with greater circuit densities imposes corresponding demands on the materials, structures, and processes used in the fabrication of integrated circuit packages. Alongside these trends toward greater integration and performance, however, there exists the perpetual pursuit for reduced manufacturing costs.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some embodiments described herein cover a first system. The system includes a vacuum chuck configured to secure a substrate. The system further includes a substrate flattening unit configured to apply a downward force to a top surface of the substrate to flatten the substrate on the vacuum chuck. The system further includes one or more sealing members configured to form a vacuum seal between the vacuum chuck and the substrate proximate to one or more peripheral edges of the substrate when the substrate is flattened by the substrate flattening unit.

Additional or related embodiments described herein cover a second system. The system includes a vacuum chuck configured to secure a substrate. The system further includes one or more clamps deployable to the vacuum chuck and configured to hold the substrate proximate to one or more peripheral edges of the substrate to secure the substrate to the vacuum chuck.

Further embodiments described herein cover a method. The method includes receiving a substrate on a vacuum chuck. The method further includes flattening, by a substrate flattening unit, the substrate on the vacuum chuck. A vacuum seal is formed between the vacuum chuck and the substrate by one or more sealing members responsive to the flattening.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The disclosure will be understood more fully from the detailed description below and from the accompanying drawings of various embodiments of the disclosure. The drawings are notably illustrative in nature and should not be taken to limit the disclosure to specific embodiments. Instead, they should be considered broadly for the explanation and teachings that they may provide.

FIG. 1A illustrates a perspective view of an advanced packaging system in accordance with at least one embodiment of the present disclosure.

FIG. 1B illustrates a side view of the advanced packaging system of FIG. 1A with a substrate flattening unit in a fully raised position.

FIGS. 2A-C are cutaway views illustrating a system to assist vacuum chucking of a substrate in accordance with at least one embodiment of the present disclosure.

FIGS. 3A-C are cutaway views illustrating a system to assist vacuum chucking of a substrate in accordance with at least one embodiment of the present disclosure.

FIGS. 4A-B are cutaway views illustrating a system to assist vacuum chucking of a substrate in accordance with at least one embodiment of the present disclosure.

FIG. 5 illustrates a flow diagram of an example method for operating a system to assist vacuum chucking of a substrate in accordance with at least one embodiment of the present disclosure.

FIG. 6 illustrates a block diagram of an example computer system in accordance with at least one embodiment of the present disclosure.

### DETAILED DESCRIPTION

The present disclosure generally relates to the field of semiconductor device manufacturing and more particularly to systems, methods, and apparatuses for securing a substrate on a vacuum chuck.

Several advanced packaging (AP) technologies have emerged to meet current demands, including a variety of different wafer level packaging (WLP) and panel level packaging (PLP) techniques. Manufacturing systems that employ such techniques will typically secure a wafer or panel substrate to a high-precision movable stage for processing (e.g., to perform a microlithography process thereon). The substrate, for example, may be secured using a chucking mechanism, such as a vacuum chuck, that may operate to pull the substrate downward and secure it onto the stage.

In some cases, however, the substrate may not be entirely flat (e.g., due to warpage from previous processing and/or handling) such that securing the substrate using a chucking mechanism alone is practically infeasible. For example, to vacuum chuck a highly warped panel or substrate (e.g., exhibiting 6 mm or more of warpage), a significant amount of air flow (e.g., in excess of 700 L/min) would be needed (i.e., to flatten and secure the substrate). Existing chucking mechanisms are unable to produce these high flow rates and would need to be modified in order to do so. To produce these high flow rates, for instance, many additional pneumatic lines would need to be drawn to the processing stage. Doing so would adversely affect stage performance, for example, by impacting the precision of its movement (e.g., on account of a tension placed on the stage by the pneumatic lines pulling). Furthermore, this high flow capability is only used for a brief period (i.e., during securement) and only needed in the substrate loading/unloading area, such that modifying the system in this way-which is itself a non-trivial undertaking-would not be worth the benefits it would provide, particularly at the expense of stage performance.

Moreover, the edges of a warped substrate or panel are particularly resistant to flattening on a vacuum chuck. The edges of a warped panel or substrate may tend to lift off of the vacuum chuck, causing a vacuum leak between the panel or substrate and the surface of the vacuum chuck. The vacuum leak can further hinder the chucking of the warped substrate or panel. Without an effective vacuum seal at the periphery of the panel or substrate, the panel or substrate may remain at least partially warped on the vacuum chuck.

Embodiments of the present disclosure address the above-mentioned challenges by forming a vacuum seal that is proximate to the peripheral edges of a substrate (e.g., or panel) to better chuck the substrate by vacuum. In some embodiments, the vacuum seal is formed by one or more sealing members. The one or more sealing members may be seals, such as an o-ring seal, a lip seal, or a gasket seal, etc. In some embodiments, a substrate flattening unit (e.g., a substrate pushing unit, etc.) is used to flatten the substrate and/or to compress the one or more sealing members so that the vacuum seal can be formed between the substrate and the vacuum chuck. In some embodiments, one or more sealing members may include clamping members (e.g., clamps) to mechanically secure the edges of the substrate to the vacuum chuck so that a vacuum seal is formed between the substrate and the surface of the vacuum chuck. In some embodiments, the clamping members are deployed to the vacuum chuck by the substrate flattening unit and are removably coupled with the vacuum chuck to secure the substrate to the vacuum chuck. In other embodiments, the clamping members are coupled to the vacuum chuck and actuate to flatten and secure the substrate to the vacuum chuck.

Embodiments of the present disclosure provide advantages over conventional solutions. By providing one or more sealing members and/or one or more clamping members, a warped substrate (e.g., or a warped panel) can be securely chucked on the surface of a vacuum chuck for processing. Particularly, the edges of the warped substrate can be held flat on the vacuum chuck because of the effective vacuum seal formed between the substrate and the vacuum chuck. By ensuring that the edges of the substrate are flat on the vacuum chuck, processing operations can be performed with respect to the substrate more uniformly, which in turn can lead to increased yield.

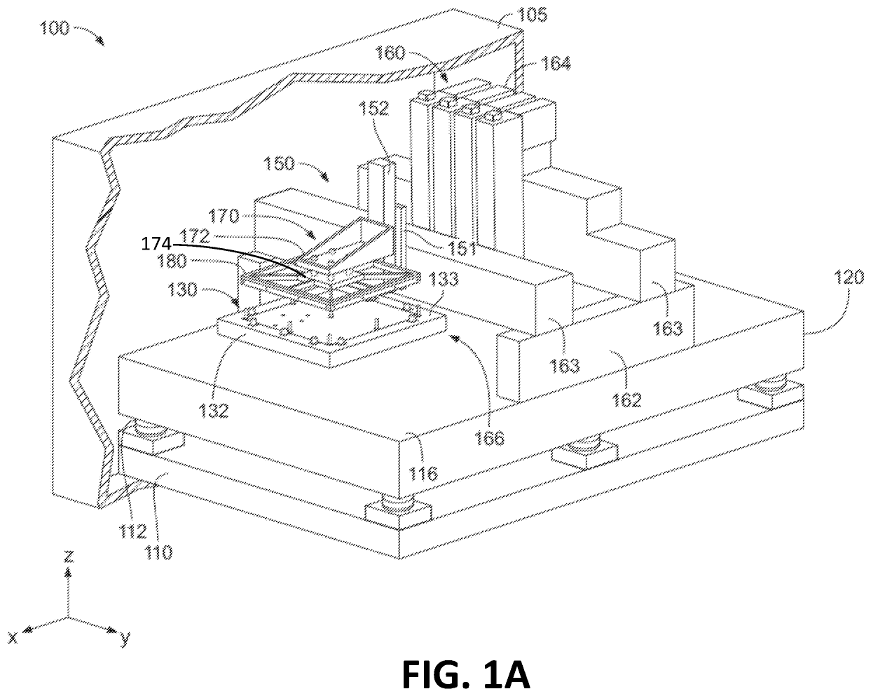

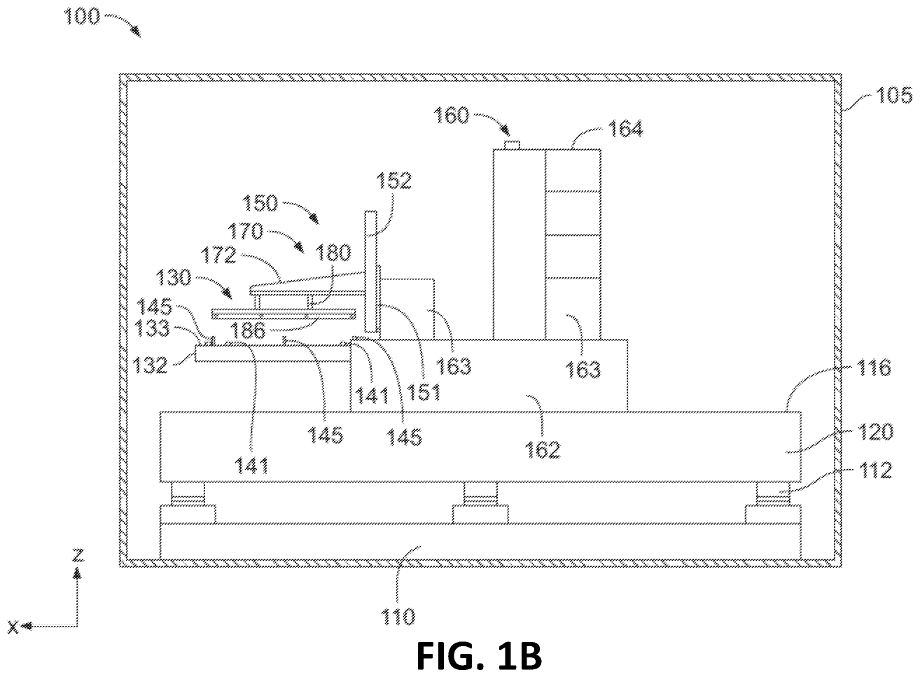

FIGS. 1A-B (collectively FIG. 1) illustrate views of an advanced packaging system 100 for processing a substrate (not shown in FIG. 1) in accordance with at least one embodiment of the present disclosure. Advanced packaging system 100 may include a base frame 110, a slab 120, a stage 130, and a processing apparatus 160, which may be enclosed within a processing chamber formed by enclosure 105. Stage 130 may be adapted to receive one or more substrates (e.g., from a robot or end effector (not shown in FIG. 1)) and secure the substrates for processing (e.g., to a chuck 132 of stage 130). In some cases, a substrate may not be entirely flat (e.g., due to warpage from previous processing and/or handling) and may be secured with the assistance of a substrate flattening unit 150. Once secured, the substrate may be moved under processing apparatus 160 for processing. Additional detail regarding advanced packaging system 100 and its components is provided below.

A substrate may take a variety of forms (e.g., varying in material, size, shape, weight, etc.) depending on the embodiment and its application. In some embodiments, for example, a substrate may be a wafer or panel made of quartz, silicon, or glass (e.g., borosilicate glass), plastic, or other suitable material for electronic device formation. In some embodiments, a substrate may have a photoresist layer formed on its surface (e.g., a top and/or bottom surface), on which a pattern forming photolithography process may be performed.

In some embodiments (e.g., as in FIG. 1), a substrate may be a rectangular substrate (e.g., a substrate panel, glass carrier panel, glass core panel, etc.) having a particular length and width (e.g., 510 mm×515 mm, 650 mm×550 mm, etc.), thickness (e.g., between 200 μm and 3.5 mm), and weight (e.g., between 100 g and 3.5 kg). In other embodiments, a substrate may be a round or disk-shaped substrate (e.g., a silicon wafer, glass carrier wafer, etc.) having a particular diameter (e.g., up to 300 mm) and thickness (e.g., between 500 μm and 1.7 mm). Advanced packaging system 100 may handle a number of different substrates during operation. In some embodiments, for example, advanced packaging system 100 may handle substrates having a same or similar shape and dimension (e.g., 510 mm×515 mm rectangular substrates, or 300 mm round substrates) but with varying thicknesses.

In some embodiments, a substrate may have one or more areas (e.g., on a top and/or bottom surface) that are suitable for handling and/or contact (e.g., that are not being employed to create electrical features). Such areas may be referred to as exclusion areas or edge exclusion areas. In some examples, a substrate may include a narrow region (e.g., 6 mm in width, 3 mm in width, etc.) around a perimeter of a top surface. The narrow region may be suitable for contact.

Substrates may be generally flat in nature but may exhibit some amount of variation in flatness across their surface (e.g., variations in a Z direction relative to an X and/or Y dimension). Substrates, for example, may be warped to varying degrees (e.g., on account of prior processing and/or handling). A substrate, for instance, may exhibit some amount of concavity or convexity and/or have wave like variations across its surface. In some embodiments, an amount of variation in the flatness of a substrate (e.g., an amount of warpage) may be specified in terms of a largest distance between a bottom side of the substrate and a top surface of an object on which the substrate may be disposed (e.g., a top surface of chuck 132 of stage 130 on which a substrate may be received). Advanced packaging system 100 may be adapted to handle substrates having varying amounts of flatness variation (or warpage) (e.g., up to 20 mm of warpage).

Enclosure 105 may be adapted to control a processing environment for processing a substrate. In some embodiments, for example, enclosure 105 may be a safety enclosure adapted to control the temperature, pressure, humidity, and/or other environmental parameters of the chamber within enclosure 105 in which base frame 110, slab 120, stage 130 (and any substrates thereon), substrate flattening unit 150, and processing apparatus 160 may be housed. In some embodiments, enclosure 105 may also operate to maintain the processing chamber in a clean state, for example, by capturing and exhausting debris particles from there within (e.g., that may be produced during processing and/or handling of a substrate).

Base frame 110 may rest on the floor of a fabrication facility and may support slab 120, which may be a monolithic structure such as a large piece of granite or stone. Base frame 110 and slab 120 may provide a rigid and stable base on which stage 130 and processing apparatus 160 may be disposed. In some embodiments, active and/or passive air isolators 112 may be positioned between base frame 110 and slab 120 and may operate to provide vibration isolation and improve slab stability.

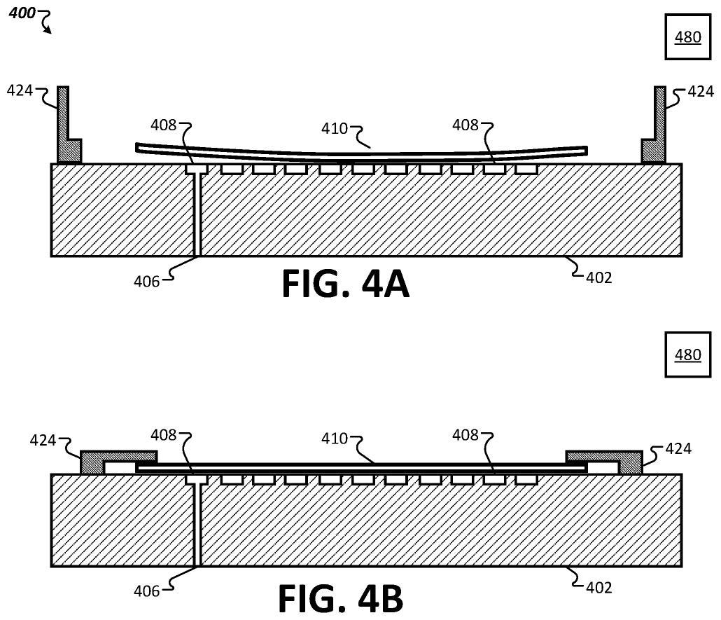

Stage 130 may be movably disposed on slab 120 and adapted to receive and secure a substrate for processing (e.g., by processing unit 164 of processing apparatus 160). While FIG. 1 illustrates a single stage 130, advanced packaging system 100 may include fewer or more stages in other embodiments and may be adapted to receive and secure multiple substrates for processing (e.g., as in the embodiment of FIG. 4).

In some embodiments, for example, advanced packaging system 100 may include one or more drive systems that may provide for independent positioning and movement of stage 130 (e.g., in an X, Y, and/or Z direction relative to slab 120). In some embodiments, the drive systems may provide for high-precision positioning and/or movement of stage 130 (e.g., at a micro or nano scale). In some embodiments, for instance, advanced packaging system 100 may include a linear drive system that can move stage 130 independently in the X direction (or an X drive system) and a linear drive system that can move stage 130 independently in the Y direction (or a Y drive system). In some embodiments, for example, an X drive system and a Y drive system may comprise one or more linear motors (e.g., cylindrical, U-channel, or flat type linear motors) to control movement of stage 130 (e.g., to a particular position at a desired velocity and/or rate of acceleration).

In some embodiments, for instance, an X drive system may include one or more forcers (e.g., having wire coils provided therein) that may move along one or more corresponding magnetic tracks, which may be disposed on a top surface 116 of slab 120 and oriented in the X direction. In some embodiments, for example, a pair of forcers may be coupled to opposite sides of a first support body of stage 130 (not shown in FIG. 1), such as a carriage or a slide. In this way, movement of the forcers along the magnetic tracks may affect movement of the first support body (and stage 130) in the X direction relative to top surface 116 of slab 120. A Y drive system, similarly, may include one or more forcers (e.g., having wire coils provided therein) that may move along on one or more corresponding magnetic tracks, which may be disposed on a top surface of the first support body and oriented in the Y direction. In some embodiments, for example, a forcer may be coupled to a second support body of stage 130 (not shown in FIG. 1), such as a carriage or slide. In this way, movement of the first support body may affect movement of the second support body in the X direction, and movement of forcers of the Y drive system along its corresponding magnetic track may affect movement of the second support body in the Y direction (i.e., relative to a top surface of the first support body and top surface 116 of slab 120). In some embodiments, advanced packaging system 100 may include one or more bearings (not shown in FIG. 1) to facilitate movement of stage 130. In some embodiments, for instance, system 100 may include air bearings disposed between the first support body and top surface 116 of slab 120 and air bearings disposed between the second support body and top surface 116 of slab 120 that may provide pressurized air to levitate stage 130 during movement.

During operation, stage 130 may move from a home position (or a load/unload position), where stage 130 may be accessible (e.g., to a robot or end effector), to a processing position wherein stage 130 may pass under processing apparatus 160 and processing unit 164 thereof. It will be appreciated that a processing position may refer to one or more positions of stage 130 under processing apparatus 160 and/or processing unit 164. Likewise, a home position (or load/unload position) may be any position of stage 130 that is clear of the processing apparatus 160 and/or where stage 130 may be accessible (e.g., by a robot or end effector).

During operation, after a substrate has been loaded onto stage 130 (e.g., at a home position), stage 130 may be lifted (in the Z direction) by air bearings disposed between stage 130 and the planar surface 116 of the slab 120. An X drive system may be actuated to move stage 130 in the X direction into opening 166 of support 162. In some embodiments, a Y drive system may be used to move stage 130 laterally relative to support 162 (i.e., in the Y direction) while stage 130 is disposed within opening 166. Air bearings may be used to provide frictionless movement of stage 130 in either of the X and Y directions. The movement of the stage 130, actuation of the air bearings, as well as control of the processing unit 164 may be provided by a controller (as discussed below).

In some embodiments, one or more encoders, sensors, and/or accelerometers may be used to provide positional information (and optionally velocity and/or acceleration information). In some embodiments, for example, an encoder may be coupled to stage 130 that may determine a position (and optionally a velocity and/or acceleration) of the stage, and any substrate thereon, which may be provided to a controller (not shown in FIG. 1). In some embodiments, for instance, an encoder may be an optical encoder. In some cases, an actual position of stage 130 and the position measured by an encoder may differ. In some embodiments, a plurality of interferometers (not shown in FIG. 1) may be used in order to more accurately measure the position of stage 130 and any substrate thereon. In some embodiments, a more accurate position measurement may be provided by one or more additional sensors. In some embodiments, for example, a plurality of interferometers (not shown in FIG. 1) may be disposed on slab 120 and aligned with mirrors (not shown in FIG. 1) coupled to stage 130. The mirrors may be positioned closer to a substrate than the encoder, and thus may provide a more accurate position measurement. A number of different types of interferometers may be used depending on the embodiment and its application. In some embodiments, for example, high stability plane mirror (HSPM) interferometers may be used. The positional information measured by the interferometers may be provided to the controller (not shown in FIG. 1).

As noted above, stage 130 may be adapted to receive and secure substrates for processing. In some embodiments, for example, stage 130 may include a chuck 132 on which substrate may be received. Chuck 132 may be coupled atop (or integrally formed as part of) a second support body of stage 130. The form of chuck 132 (e.g., material size, shape, etc.) may vary depending on the embodiment and its application (e.g., depending on the shape and size of substrates that may be received). In some embodiments, for example, chuck 132 may be made of the same material as the second support body, such as aluminum. In some embodiments, chuck 132 may be made of (or coated with) a different material, such as silicon or a ceramic material, which may help to reduce backside contamination of a substrate. In some embodiments, chuck 132 may be rectangular in form, while in others, chuck 132 may be round or disk-shaped. In some embodiments, chuck 132 may have a surface area of approximately 1 square meter, though larger or smaller chucks may be suitable for other embodiments and applications. In some embodiments, one or more sealing members are configured to form a vacuum seal between the chuck 132 and a substrate disposed on the chuck. The vacuum seal may be formed responsive to a downward force provided by the pushing unit 150. In some embodiments, one or more clamps are configured to secure a substrate to chuck 132.

In some embodiments, stage 130 may include a plurality of lift pins 145 and clamp pins 141 that may be used to receive and position a substrate on chuck 132. In some embodiments, for example, chuck 132 may have a plurality of clearance holes formed therethrough, which may be sized and shaped so as to accommodate lift pins 145 therein, and may have a plurality of slots formed therethrough, which may be sized and shaped so as to accommodate and permit movement of clamp pins 141 therein. In some embodiments, lift pins 145 may be coupled to (or integrally formed as part of) a lift pin structure disposed within a second support body, which may be coupled to one or more lift pin actuators that may operate to move lift pin structure (and lift pins 145) in the Z direction (i.e., through corresponding clearance holes). Lift pin actuators, for example, may operate to move the lift pin structure from an initial position, where lift pins 145 are fully recessed below a top surface 133 of chuck 132 and/or within a second support body, to a final position, where lift pins 145 are fully raised (i.e., through clearance holes and beyond top surface 133 of chuck 132).

Lift pins 145 may be appropriately positioned and of sufficient length to facilitate substrate transfer by a robot or end effector (e.g., providing adequate space between lift pins 145 and between top surface 133 of chuck 132 and a lower surface of a substrate that may rest there upon). The robot or end effector, for instance, may provide substrates through a port (not shown in FIG. 1) in enclosure 105 and may position substrate on raised lift pins 145 (e.g., after moving lift pin actuator 146 to a final position). Lift pins 145 may thereafter gently lower the substrate onto chuck 132 (e.g., by moving lift pin actuators 146 to an initial position).

When a substrate is initially received on chuck 132 (e.g., from the robot or end effector), it may not be in the exact position desired for processing (e.g., which may benefit from the substrate being consistently positioned on chuck 132). In some embodiments, stage 130 may include a plurality of clamp pins 141 that may help to receive and reposition substrate on chuck 132 to a desired position before it is secured for processing. Clamp pins 141 may be made of or covered with a material suitable for contacting substrate (e.g., nonmarring, producing minimal debris particles, etc.). In some embodiments, for example, an engineered thermoplastic may be used, such as polyetheretherketone (PEEK), polyphenylene sulfide (PPS), or other high-performance semicrystalline thermoplastic. In some embodiments, a subset of the plurality of clamp pins 141 may serve as banking clamp pins (or reference clamp pins) that may help receive a substrate (e.g., by a robot or end effector), for example, by serving as a bank or reference against which a substrate may be placed. In some embodiments, another subset of the plurality of clamp pins 141 may serve as pushing clamp pins that may reposition the substrate once received. In some cases, a clamp pin 141 may serve as both a banking clamp pin and a pushing clamp pin.

In some embodiments, clamp pins 141 may be coupled to (or integrally formed as part of) a clamp structure (not shown in FIG. 1) disposed within the second support body, which may be coupled to one or more clamp actuators (not shown in FIG. 1) that may operate to move the clamp structure and clamp pins 141 in the Z direction (i.e., through corresponding slots). The clamp actuators, for example, may operate to move the clamp structure from an initial position, where clamp pins 141 are fully recessed below a top surface 133 of chuck 132 and/or within the second support body, to a final position, where clamp pins 141 are fully raised (i.e., through slots 139 and beyond top surface 133 of chuck 132). In some embodiments, the clamp actuators (or a portion thereof) may also operate to move the clamp structure and clamp pins 141 medially (e.g., in an X and/or Y direction or a radial direction), for example, from an initial outer position to a final inner position.

In some embodiments, stage 130 may include a mechanism to secure substrates thereto (e.g., to chuck 132). In some embodiments, for example, stage 130 may include a chucking mechanism (e.g., a vacuum chucking mechanism, an electrostatic chucking mechanism, or the like) that may operate to apply a downward pulling force on a substrate and secure it to chuck 132. In some embodiments, for example, a vacuum chucking mechanism may include a vacuum source (not shown in FIG. 1) that may be in fluid communication with one or more ports or apertures formed in chuck 132. The vacuum source may operate to pull air through the apertures, which may apply a downward pulling force on a substrate pulling it toward chuck 132 and secure it thereto. The pulling force may draw the substrate into contact with the apertures, such that once the substrate is secured, air may no longer flow through the apertures and a vacuum pressure may drop.

In some embodiments, the vacuum chucking mechanism may provide for different chucking zones. In some embodiments, for example, the vacuum source may be able to pull air through the apertures independently and may operate to pull air through a subset of one or more of the apertures to provide different chucking zones. For example, as illustrated in FIG. 1, each of the apertures may provide for four separate chucking zones. In some embodiments, each a chucking zone may be further segmented into a number of different zones, for example, an outer and inner zone.

As noted above, a substrate may exhibit some amount of warpage (or other variations in its flatness), in which case the downward pulling force may operate to flatten the substrate. The amount of force to flatten a substrate may depend on the amount of substrate warpage. In some cases, where a substrate exhibits a significant amount of variation (e.g., a significant amount of warpage), the downward pulling force produced by the chucking mechanism (e.g., vacuum chuck) alone may not be sufficient to flatten the substrate. In such cases, a substrate flattening unit 150 may be used to apply a downward pushing force to help flatten the substrate (as discussed in further detail below).

It will be appreciated that advanced packaging system 100 may include a number of elements not shown in FIG. 1 in order to provide for fluid communication between the apertures and a vacuum source and facilitate the flow of air therethrough, including for example, one or more pneumatic tubes, lines, pumps, valves, regulators, filters, manifolds, or the like.

In some embodiments, stage 130 may include one or more sensors that may provide information that is used during processing of a substrate. In some embodiments, for example, stage 130 may include one or more substrate presence sensors (e.g., an optical sensor) that may be able to detect the presence of a substrate on a top surface 133 of chuck 132. In some embodiments, for instance, the substrate presence sensors may be disposed within chuck 132 (and/or a second support body), which may include one or more slots in its top surface 133 through which the optical sensors may be able to detect the presence of a substrate.

Processing apparatus 160 may comprise a support 162 (e.g., disposed on slab 120) and a processing unit 164 secured thereto for processing substrates. In some embodiments, for example, support 162 may be a gantry structure having a plurality of bridges 163 that span slab 120 (e.g., in the Y direction) and provide an opening 166 thereunder. Processing unit 164 may be secured to bridges 163 and disposed above opening 166, which may be suitably sized to permit stage 130 to pass under processing unit 164 and allow processing unit 164 to operate on any substrates provided thereon.

In some embodiments, for example, processing unit 164 may be a pattern generator configured to expose a photoresist disposed on a substrate to a photolithography process. Processing unit 164, for instance, may be a pattern generator configured to perform a maskless lithography process. In some embodiments, processing unit 164 may include one or more image projection systems disposed in a housing that may direct one or more light sources onto specific areas of a photoresist (e.g., as a substrate passes under the processing apparatus 160). The image projection systems, for example, may be part of a digital light projector device that utilizes laser light. In some embodiments, multiple laser light sources may be combined and projected onto a digital micro-mirror (e.g., a multi-faceted mirror) that redirects the light onto specific areas of the photoresist.

Substrate flattening unit 150 may be disposed above stage 130 used to help secure a substrate thereto. For example, in instances where a substrate is warped, substrate flattening unit 150 may be used to apply a downward pushing force to the substrate to help flatten the substrate and allow for its securement to stage 130 (e.g., using a vacuuming chuck).

In some embodiments, for example, substrate flattening unit 150 may be secured to support 162 of processing apparatus 160, which may provide a stable and rigid support for substrate flattening unit 150 and allow substrate flattening unit 150 to be positioned above stage 130 with minimal impact on stage accessibility (e.g., by a robot or end effector). In some embodiments, for instance, a bridge connecting plate 151 may be used to secure substrate flattening unit 150 to a bridge 163 of support 162. Bridge connecting plate 151, for instance, may be used to rigidly couple linear actuator 152 to a outer lateral surface (e.g., in the X direction) of a bridge 163 such that substrate flattening unit 150 may be disposed over stage 130 when in a load/unload position.

Linear actuator 152 may support a push assembly 170, which may be coupled thereto, and may operate to move push assembly 170 in a Z direction (e.g., relative to stage 130). Linear actuator 152, for example, may be able to move push assembly 170 from a retracted or fully raised position to a fully lowered position. Push assembly 170 may be placed in a fully raised position when not in use. In the fully raised position, adequate space may be provided between a bottom of push assembly 170 and chuck 132 to permit loading/unloading of a substrate thereto/therefrom (e.g., by a robot or end effector). Because push assembly 170 may be suspended when not in use, push assembly 170 may be designed so as to minimize vibration when stationary (e.g., having a first modal frequency above 100 Hz and/or a magnitude of no more than 5 μm). In this way, push assembly 170 may not unduly interfere with (e.g., introduce vibration into) system 100 when performing other processing operations (e.g., microlithography processing performed by processing unit 164).

Linear actuator 152 may lower push assembly 170 (e.g., from a fully raised position) when assistance with securement of a substrate is desired. In some embodiments, for example, linear actuator 152 may initiate lowering of push assembly 170 based upon a determination that an initial attempt at securing a substrate was unsuccessful and that assistance is needed. For instance, where a vacuum chucking mechanism is being used, a determination that an initial attempt was unsuccessful may be made based on feedback provided by a vacuum source (e.g., a vacuum pressure and/or air flow rate). For example, a determination that an initial attempt was unsuccessful may be made if a vacuum pressure does not drop (e.g., below a threshold amount) or if an air flow rate is high (e.g., above a threshold leakage amount) for an extended period of time, as this may indicate that a substrate has not been successfully drawn into contact with the apertures of chuck 132.

As pushing assembly 170 is lowered, it may be brought into contact with and apply a downward pushing force onto a substrate. In the fully lowered position, the substrate may be flattened and secured to chuck 132. Once secured, linear actuator 152 may return pushing assembly 170 to a fully raised position. In some embodiments, for example, linear actuator 152 may initiate return of pushing assembly 170 based upon a determination that the substrate was successfully secured to chuck 132. For instance, where a vacuum chucking mechanism is being used, a determination that the substrate was successfully secured may be made based on feedback provided by a vacuum source (e.g., based on an observed drop in vacuum pressure and/or a de minimis air flow rate).

In order to minimize a processing time of a substrate, linear actuator 152 may operate to move pushing assembly 170 (e.g., between a fully raised position to a fully lowered position and back) as quickly as possible. For example, in performing a downside or upside move, linear actuator 152 may accelerate as quickly as possible to reach a set speed (e.g., a maximum speed of linear actuator 152), move at the set speed for as long as possible, and decelerate as quickly as possible (e.g., to arrive at a final position). In some embodiments, linear actuator 152 may limit a speed at which pushing assembly 170 may travel when approaching a substrate (e.g., in a downside move), so as to minimize an impact when it is brought into contact with the substrate and avoid producing debris particles and/or damaging the substrate.

A number of different types of linear actuators 152 (e.g., stepper or servomotor driven ball screw or belt actuators) may be used depending on the embodiment and its application. A suitable linear actuator 152, for example, may be selected based on a number of different parameters, including a workload capacity (e.g., a maximum weight of pushing assembly 170 that can be supported), speed (e.g., a maximum speed at which pushing assembly 170 can be moved), positioning repeatability (e.g., a precision with which pushing assembly 170 can be moved), and/or clean room class (e.g., a maximum number of particles that may be produced). In some embodiments, for instance, linear actuator 152 may be a Class-10 linear actuator that includes a rotary servo (or stepper) driven motor, which drives a ball screw actuator, and has a workload capacity of 20 Kg, maximum speed of 1200 mm/s, and a positioning repeatability of ±0.02 mm.

Pushing assembly 170 may be used to apply a downward pushing force onto a substrate (e.g., as pushing assembly 170 is lowered by linear actuator 152). In some embodiments, for example, pushing assembly 170 may include a push frame 180 adapted to apply the downward pushing force onto a substrate. In some embodiments, for example, push frame 180 may have a contact pad 186 provided thereon that may contact a substrate to apply the downward pushing force.

The form of push frame 180 and contact pad 186 (e.g., material, size, shape, etc.) may vary depending on the embodiment and its application (e.g., depending on the shape and size of the substrates being secured). In some embodiments, for example, push frame 180 may be made of aluminum or other suitable material (e.g., light weight, inexpensive, etc.), and contact pad 186 may be made of or coated with a material suitable for contacting a substrate (e.g., nonmarring, producing minimal debris particles, etc.). In some embodiments, for example, contact pad 186 may be made of (or coated with) an engineered thermoplastic, such as polyetheretherketone (PEEK), polyphenylene sulfide (PPS), or other high-performance semicrystalline thermoplastic.

Push frame 180 may have a similar shape and size as a substrate being secured, such that push frame 180 may apply a generally uniform force to the substrate. Push frame 180 may also be shaped and sized so as to generally overlap with areas of a substrate that are suitable for contact and/or handling when positioned over the substrate. In some embodiments, push frame 180 may include one or more cavities through which air may flow, which may help to reduce the impact that push frame 180 may have on air circulation within enclosure 105. By way of example, push frame 180 may be generally rectangular in form and may comprise an outer ring portion connected to a central portion by a plurality of arms. When positioned over a substrate, the outer ring portion and a subset of the arms may be disposed generally above handling and/or contact regions of the substrate.

Contact pad 186 may be coupled to push frame 180 and may be shaped and sized so as to align with areas of a substrate that are suitable for handling and/or contact. In some embodiments, for example, contact pad 186 may be a relatively thin (e.g., having a thickness of 5-6 mm in the X-Y plane) rectangular ring that when coupled to push frame 180 may align with a perimeter of a substrate, which may be suitable for contact and/or handling.

In some embodiments, push frame 180 may be flexibly and adjustably coupled to linear actuator 152. In some embodiments, for example, actuator bracket 172 may be secured to linear actuator 152 and may cantilever over stage 130. Actuator bracket 172, in turn, may be coupled to a flexure 174. In some embodiments, for example, actuator bracket 172 may be coupled to flexure 174 by a plurality of adjustment studs. The adjustments studs may be individually and/or collectively adjusted to control an orientation (e.g., a pitch, yaw, and or roll) of push frame 180 relative to chuck 132 of stage 130. In this way, a motion axis of push frame 180 (e.g., as pushing assembly 170 is lowered) may be aligned perpendicular to chuck 132 so as to apply a uniform pushing force to a substrate provided thereon.

Flexure 174 may be secured to a top surface of a central portion of push frame 180 (e.g., by a plurality of screws spaced around its perimeter) and may provide for some degree of flexibility in push frame 180 relative to linear actuator 152. For example, as push frame 180 is pushed down on a substrate, flexure 174 may bulge or flex slightly and provide a degree of compliance in a Z direction (e.g., up to 200 μm). The compliance afforded by flexure 174 may help to accommodate variations in substrate warpage and/or thickness and prevent the application of excessive force to a substrate. In some embodiments, for example, flexure 174 may be a thin stainless-steel plate (e.g., a 17-4 precipitation hardened martensitic stainless-steel) that may be removably secured to push frame 180 (e.g., by a plurality of screws spaced around its perimeter).

In some embodiments, substrate flattening unit 150 may include one or more encoders, position sensors, and/or accelerometers in order to determine a position (and optionally a velocity and/or acceleration) of pushing assembly 170, which may be used to control its movement. In some embodiments, for example, the information provided by the encoders, sensors, and/or accelerometers may be used to precisely control movement of pushing assembly 170 (and push frame 180), including initiating a speed reduction of pushing assembly 170 prior to contact with a substrate (e.g., in a downside move), and/or determine if push frame 180 is out of alignment (e.g., having a motion axis misaligned with chuck 132). In some embodiments, for example, an encoder may be provided on a motor of linear actuator 152 (e.g., a rotary encoder on a servomotor thereof) to determine a position (and optionally a velocity and/or acceleration) of pushing assembly 170 (e.g., relative to linear actuator 152). In some embodiments, an encoder may additionally (or alternatively) may be provided on the actuator of linear actuator 152 (e.g., a linear encoder on a ball screw or belt) to determine a position of pushing assembly 170 (e.g., relative to linear actuator 152), which may be relatively more accurate than the encoder provided on the motor. In some embodiments, one or more position sensors (e.g., interferometers and corresponding mirrors) and/or accelerometers may additionally (or alternatively) be provided on push frame 180 to determine a position (and optionally a velocity and/or acceleration) of push frame 180 (e.g., relative to a top surface of a substrate). In some cases, these positions sensors may provide a more accurate measurement of the position of push frame 180 (and contact pad 186).

In some embodiments, substrate flattening unit 150 may include one or more force feedback sensors that may measure a force applied by substrate flattening unit 150 (e.g., by push frame 180 and contact pad 186) to a substrate. In some embodiments, the information provided by the force feedback sensors may be used to control linear actuator 152 to control the amount of force applied to the substrate through pushing assembly 170, which may help to minimize the likelihood of damage to the substrate.

System 100 may also include a controller (not shown in FIG. 1) that may facilitate the control and operation of the components described herein to perform the processing techniques described. In some embodiments, for example, the controller may be coupled to or in communication with stage 130, substrate flattening unit 150, and processing apparatus 160, for controlling the operation thereof. The controller, for example, may control the position and movement of stage 130 (e.g., through control of an X drive system and a Y drive system), control the position and movement of pushing assembly 170 of substrate flattening unit 150 (e.g., through control of linear actuator 152), and control processing unit 164 of processing apparatus 160 (e.g., to perform a microlithography process on a photoresist provided on a substrate). The controller may also be in communication with various sensors and/or encoders of system 100, which for example, may provide information regarding a position and movement of stage 130 and substrate flattening unit 150 (or components thereof), operational information regarding a chucking mechanism (e.g., air pressure and/or air flow feedback from a vacuum source used for vacuum chucking). The controller may process the information provided by the sensors and/or encoders to control the operation of system 100 and its components (e.g., of stage 130, substrate flattening unit 150, and processing apparatus 160).

The controller may include a central processing unit (CPU) (not shown in FIG. 1 in FIG. 1), memory (not shown in FIG. 1), and support circuits (or I/O) (not shown in FIG. 1). The CPU may be one of any form of computer processors that are used in industrial settings for controlling various processes and hardware (e.g., pattern generators, motors, and other hardware) and monitor the processes (e.g., processing time and substrate position). The memory may be connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits may also be connected to the CPU for supporting the processor. The support circuits, for example, may include one or more caches, power supplies, clock circuits, input/output circuitry, subsystems, and the like. A program (or computer instructions) readable by the controller may determine which tasks are to be performed on a substrate. The program may be software readable by the controller and may include code to monitor and control, for example, the processing time and substrate position.

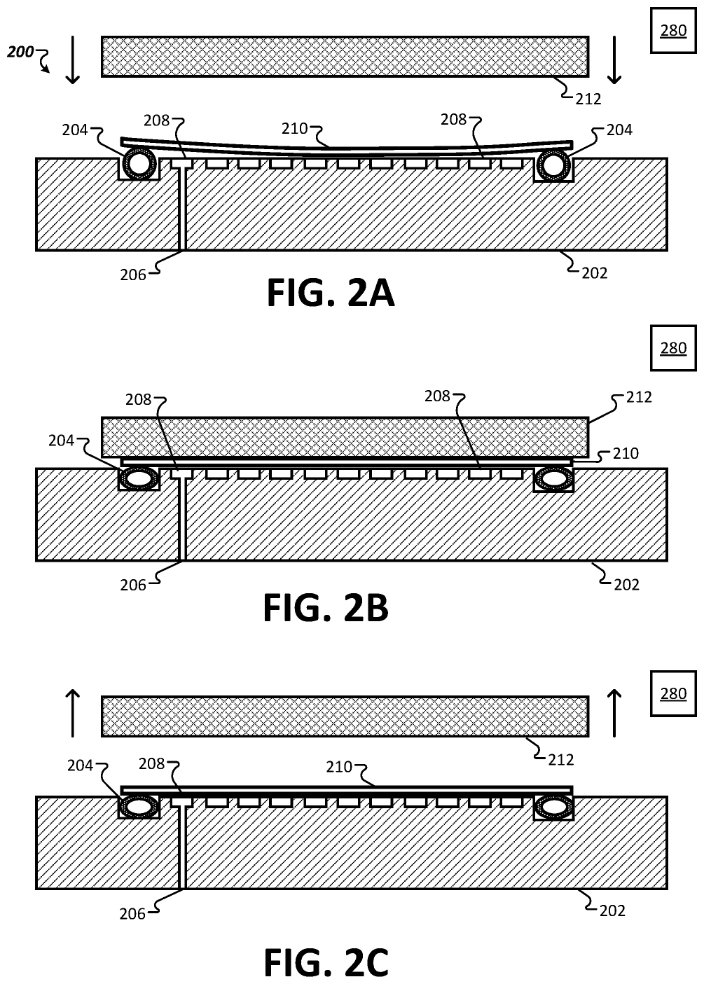

FIGS. 2A-C are cutaway views illustrating a system 200 to assist vacuum chucking of a substrate in accordance with at least one embodiment of the present disclosure.

Referring to FIG. 2A, in some embodiments, a substrate 210 is disposed on a vacuum chuck 202. The substrate may be placed on the vacuum chuck. In some embodiments, a substrate transfer robot places the substrate on lift pins and the lift pins lower the substrate onto the chuck. The vacuum chuck may be coupled to a movable stage and may be to secure the substrate to the movable stage. The substrate 210 may be warped. In some embodiments, the bottom surface of the substrate 210 may at least partially contact seals 204. In some embodiments, the seals 204 are sealing members that are to form a vacuum seal. In some embodiments, the seals 204 can be an o-ring seal (as illustrated in FIGS. 2A-C), a lip seal, or a gasket seal. In some embodiments, seals 204 are made of an elastomer material such as rubber or fluoroelastomer materials such as a thermoplastic fluoropolymer, polytetrafluorochylene (PTFE), expanded PTFE, etc. In some embodiments, the seals 204 are a single-piece seal that extends around the periphery of the substrate 210. The seals 204 may have a ring-shaped profile (e.g., such as for substrates that are circular, have a circular perimeter profile, etc.), or may have a square- or rectangular-shaped profile (e.g., such as for substrates that are square or rectangular, have a square or rectangular perimeter profile etc.). The substrate 210 may contact the seals 204 proximate to the peripheral edge(s) of the substrate 210. In some embodiments, the seals 204 fit into a groove formed in the top surface of the vacuum chuck 202.

In some embodiments, air may be sucked through the apertures 208 and directed through vacuum outlet 206 (e.g., to a vacuum source). Although the substrate 210 may be at least partially in contact with the seals 204 as shown in FIG. 2A, in some embodiments, the substrate 210 may not be effectively secured to the vacuum chuck 202 because of vacuum leaks at the edges of the substrate 210. The vacuum leaks may be caused by the warpage of the substrate 210. In some embodiments, a substrate flattening unit 212 (e.g., such as substrate flattening unit 150) is actuated downward to flatten the substrate 210 (e.g., to remove the warpage, etc.). The substrate flattening unit 212 may contact the substrate 210 on an edge exclusion zone of the substrate 210. In some embodiments, controller 280 controls the actuation of the substrate flattening unit 212 and/or the vacuum source fluidly coupled with the vacuum outlet 206.

Referring to FIG. 2B, in some embodiments, the substrate flattening unit 212 is actuated downwards and makes contact with the top surface of the substrate 210. The substrate flattening unit 212 may contact the substrate 210 on the edge exclusion zone of the substrate 210. As the substrate flattening unit 212 exerts a downward force on the top surface of the substrate 210, the substrate 210 may become flattened. In some embodiments, the downward force applied by the substrate flattening unit 212 pushes against the substrate 210 (especially at the peripheral edges of the substrate 210) and may compress the seals 204. In some embodiments, the seals 204 are compressed within the groove in the vacuum chuck 202. In some embodiments, the downward force provided by the substrate flattening unit 212 is to flatten the substrate 210 and compress the seals 204. In some embodiments, a vacuum seal is formed between the compressed seals 204 and the bottom surface of the flattened substrate 210 proximate to the peripheral edges of the substrate 210.

Referring to FIG. 2C, in some embodiments, the substrate flattening unit 212 is actuated upwards to retract from the substrate 210. In some embodiments, the vacuum chuck 202 is to retain the substrate 210 in a flattened state responsive to flattening of the substrate by the substrate flattening unit. Because of the vacuum seal formed between the seals 204 and the bottom surface of the flattened substrate 210, substantially no vacuum leaks may exist at the edges of the substrate 210. By substantially eliminating the vacuum leaks at the edges of the substrate 210 (e.g., by flattening the substrate 210), vacuum pressure through the apertures 208 and the vacuum outlet 206 may decrease and the substrate 210 may be securely chucked to the vacuum chuck 202. In some embodiments, the vacuum seal formed proximate to the peripheral edges of the substrate 210 may allow the edges of the substrate to be securely chucked to the vacuum chuck 202.

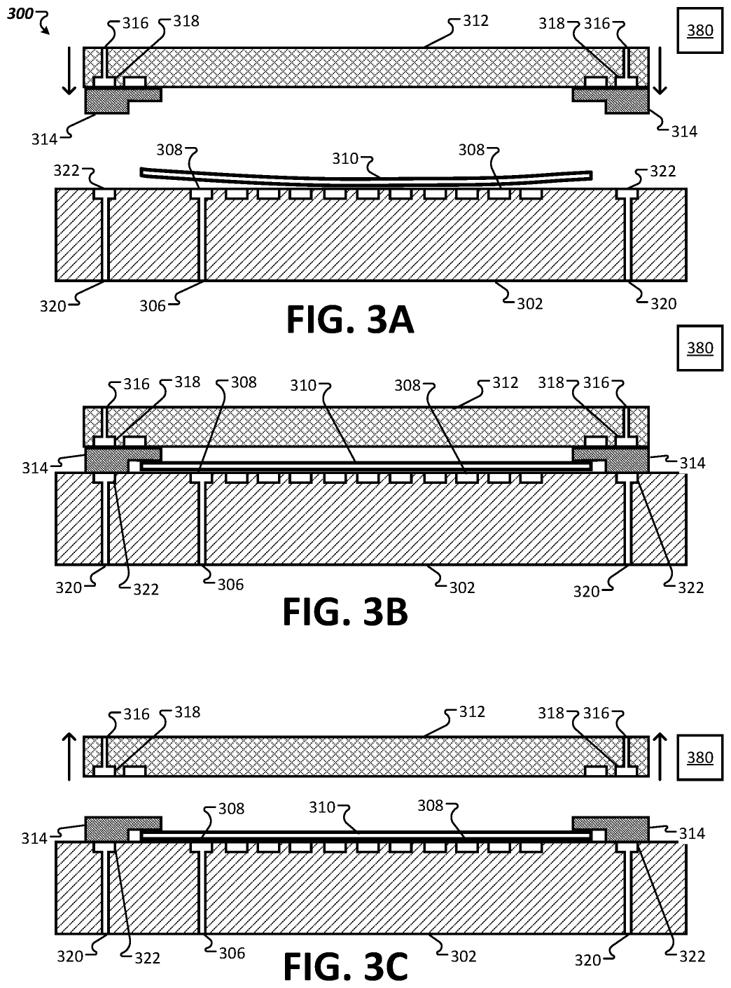

FIGS. 3A-C are cutaway views illustrating a system 300 to assist vacuum chucking of a substrate in accordance with at least one embodiment of the present disclosure. Features shown in FIGS. 3A-C having similar numbering as features illustrated in FIGS. 2A-C may have similar structure and/or function.

Referring to FIG. 3A, in some embodiments, a warped substrate 310 is disposed on a vacuum chuck 302. A vacuum source (not illustrated) may provide vacuum to chucking apertures 308 via vacuum outlet 306. Although the substrate 310 may be in at least partial contact with the vacuum chuck 302, in some embodiments, the substrate 310 may not be effectively secured to the vacuum chuck 302 because of vacuum leaks at the edges of the substrate 310. The vacuum leaks may be caused by the warpage of the substrate 310. In some embodiments, one or more mechanical clamps are deployable to the vacuum chuck 302 to secure and/or flatten the substrate 310.

In some embodiments, a substrate flattening unit 312 is configured to carry vacuum clamps 314. In some embodiments, the vacuum clamps 314 include one clamp that substantially matches the perimeter profile of the substrate 310. For example, if the substrate 310 is circular, the vacuum clamp may have a ring-shaped profile that matches the circular perimeter profile of the substrate 310. In another example, if the substrate 310 is rectangular, the vacuum clamp may have a rectangular-shaped profile that matches the rectangular perimeter profile of the substrate 310.

In some embodiments, the vacuum clamps 314 are removably coupled to the substrate flattening unit 312. For example, the vacuum clamps 314 may be removably coupled to the substrate flattening unit by a selective vacuum coupler, by a selective electromagnetic coupler, by a selective hydraulic coupler, by a selective pneumatic coupler, and/or by one or more mechanical couplers. For example, and in some embodiments, the substrate flattening unit 312 includes vacuum ports and/or passages to secure the vacuum clamps 314 to the substrate flattening unit 312 by vacuum. In some embodiments, a vacuum source (not illustrated) provides vacuum to apertures 318 via vacuum outlets 316. The vacuum provided through the apertures 318 may secure the vacuum clamps 314 to the substrate flattening unit 312 for deployment of the vacuum clamps 314 to the vacuum chuck 302. In some embodiments, the vacuum clamps 314 are removably coupled to the substrate flattening unit 312 by one or more electromagnetic couplers that can be energized or de-energized. In some embodiments, the substrate flattening unit 312 is actuated to flatten the substrate 310 and/or to deploy the vacuum clamps 314 to the vacuum chuck 302. In some embodiments, the controller 380 controls the actuation of the substrate flattening unit 312 and/or the activation and deactivation of the vacuum source(s).

In some embodiments, system 300 may include seals 204 of system 200 which may operate as described herein above.

Referring to FIG. 3B, in some embodiments, the substrate flattening unit 312 applies a downward force on the substrate 310 to flatten the substrate. In some embodiments, the vacuum clamps 314 contact the edges of the substrate 310. The vacuum clamps 314 may contact the edge exclusion zone of the substrate 310. In some embodiments, the downward force applied by the substrate flattening unit 312 substantially flattens the substrate 310. In some embodiments, the vacuum clamps 314 form sealing members that are to form a vacuum seal between the bottom surface of the substrate 310 and the top surface of the vacuum chuck 302. Contact between the vacuum clamps 314 and the substrate 310 may cause the vacuum seal to form between the substrate 310 and the vacuum chuck 302.

In some embodiments, when the substrate flattening unit 312 deploys the vacuum clamps 314 to the vacuum chuck 302, the vacuum clamps 314 may contact the vacuum chuck 302 and may cover clamping apertures 322. A vacuum source (not illustrated) may be activated to cause vacuum to be provided via clamping apertures 322 and vacuum outlets 320 to removably secure the vacuum clamps 314 to the vacuum chuck 302 by vacuum force. In some embodiments, the vacuum clamps 314 are removably coupled to the vacuum chuck 302 by one or more electromagnetic couplers, one or more pneumatic couplers, one or more hydraulic couplers, and/or one or more mechanical couplers. In some embodiments, the vacuum sources corresponding to each of the chucking apertures 308, the clamping apertures 322, and the apertures 318 are independently controlled (e.g., by the controller 380). In some embodiments, when the vacuum clamps 314 are secured to the vacuum chuck 302 (e.g., by vacuum provided via the vacuum outlets 320 and clamping apertures 322, etc.), the vacuum provided by the apertures 318 via vacuum outlets 316 may be deactivated so that the vacuum clamps 314 are no longer coupled (by vacuum) to the substrate flattening unit 312.

Referring to FIG. 3C, in some embodiments, the substrate flattening unit 312 is actuated away from the substrate 310 and the vacuum chuck 302. Vacuum provided to the chucking apertures 322 may secure the vacuum clamps 314 to the vacuum chuck 302, which in turn secure the substrate 310 to the vacuum chuck 302. In some embodiments, the vacuum clamps 314 secure the edges of the substrate 310 so that the substrate 310 remains substantially flat on the vacuum chuck 302. A vacuum seal may be formed between the bottom surface of the substrate 310 and the top surface of the vacuum chuck 302 and substantially no vacuum leaks may exist at the peripheral edges of the substrate 310 so that the substrate 310 may be securely chucked to the vacuum chuck 302. In some embodiments, the substrate 310 is secured to the vacuum chuck both by vacuum force and by the vacuum clamps 314.

FIGS. 4A-B are cutaway views illustrating a system 400 to assist vacuum chucking of a substrate in accordance with at least one embodiment of the present disclosure. Features shown in FIGS. 4A-B having similar numbering as features illustrated in FIGS. 2A-C and/or FIGS. 3A-C may have similar structure and/or function.

Referring to FIG. 4A, in some embodiments, a warped substrate 410 is disposed on a vacuum chuck 402. A vacuum source (not illustrated) may provide vacuum to apertures 408 via vacuum outlet 406. Although the substrate 410 may be in at least partial contact with the vacuum chuck 402, in some embodiments, the substrate 410 may not be effectively secured to the vacuum chuck 402 because of vacuum leaks at the edges of the substrate 410. The vacuum leaks may be caused by the warpage of the substrate 410. In some embodiments, the vacuum chuck 402 includes clamps 424. The clamps 424 may be actuatable to secure the substrate 410 to the vacuum chuck. In some embodiments, the clamps 424 are actuatable to an open position (as shown in FIG. 4A) so that a substrate 410 can be placed on the vacuum chuck 402. In some embodiments, the clamps 424 are actuatable to a closed position (as shown in FIG. 4B and discussed herein below) to secure a substrate 410 on the vacuum chuck 402. The clamps 424 may be actuatable by a hinge mechanism, a four-bar linkage mechanism, and/or a combined motion mechanism, etc. The clamps 424 may be actuated by a pneumatic actuator, a vacuum actuator, and/or an electro-mechanical actuator, etc. In some embodiments, controller 480 controls actuation of the clamps 424 and/or the activation or deactivation of the vacuum source.

In some embodiments, system 400 may include seals 204 of system 200 which may operate as described herein above.

Referring to FIG. 4B, in some embodiments, the clamps 424 are actuated to the closed position to secure the substrate 410 to the vacuum chuck 402. In some embodiments, the clamps 424 contact the edges of the substrate 410 in the edge exclusion zone. The clamps 424, when actuated to the closed position, may provide a downward force on the top surface of the substrate 410 to flatten the substrate 410 on the vacuum chuck 402. In some embodiments, the clamps 424 contact the top surface of the substrate proximate to the peripheral edges of the substrate 410 so that the edges of the substrate 410 are flattened on the vacuum chuck 402. In some embodiments, flattening the edges of the substrate 410 (e.g., by the clamps 424) causes a vacuum seal to be formed between the substrate 410 and the vacuum chuck 402 proximate to the peripheral edges of the substrate 410. Forming the vacuum seal may cause the substrate 410 to be securely chucked to the vacuum chuck 402. In some embodiments, the clamps 424 can align the substrate 410 on the vacuum chuck. For example, the clamps 424 may contact the edges of the substrate 410 to align the substrate 410 in the XY plane on the top surface of the vacuum chuck 402.

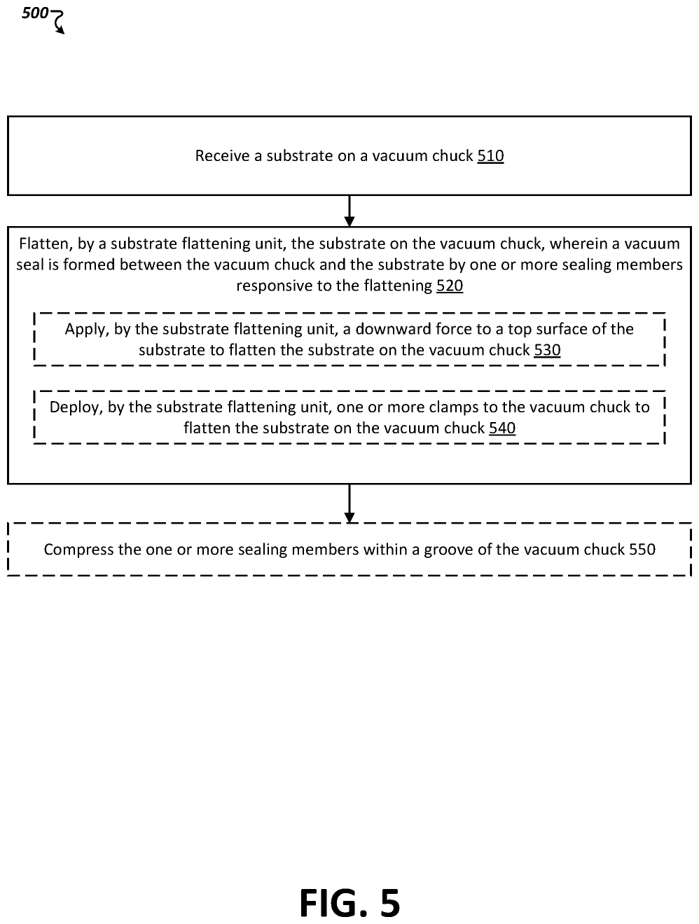

FIG. 5 illustrates a flow diagram of an example method 500 for operating a system to assist vacuum chucking of a substrate in accordance with at least one embodiment of the present disclosure. For simplicity of explanation, method 500 is depicted and described as a series of acts. However, acts in accordance with this disclosure can occur in various orders and/or concurrently, and with other acts not presented and described herein. Furthermore, not all illustrated acts may be performed to implement method 500 in accordance with the disclosed subject matter. In addition, those skilled in the art will understand and appreciate that method 500 could alternatively be represented as a series of interrelated states via a state diagram or events.

At block 510, a substrate is received on a vacuum chuck. The substrate may be a warped substrate. In some embodiments, the edges of the substrate may be warped so that at least a portion of the edge(s) do not contact the surface of the vacuum chuck.

At block 520, the substrate is flattened by a substrate flattening unit. The substrate may be flattened so that a vacuum seal is formed between the vacuum chuck and the substrate by one or more sealing members. The vacuum seal may be formed responsive to a flattening force applied by the substrate flattening unit. In some embodiments, because of the vacuum seal, the vacuum chuck can retain the substrate in a flattened state when the substrate flattening unit is actuated away from the substrate.

At block 530, a downward force is applied to a top surface of the substrate by the substrate flattening unit to flatten the substrate on the vacuum chuck. In some embodiments, the substrate flattening unit is actuated downwards to contact the warped substrate. The downward force provided by the substrate flattening unit may cause the vacuum seal to be formed proximate to the peripheral edges of the substrate.

At block 540, one or more clamps are deployed to the vacuum chuck by the substrate flattening unit to flatten the substrate on the vacuum chuck. In some embodiments, the one or more clamps are configured to removably couple to the substrate flattening unit for deployment to the vacuum chuck. In some embodiments, the one or more clamps are deployed to the vacuum chuck to secure the substrate to the vacuum chuck. The one or more clamps may be removably coupled to the vacuum chuck (e.g., by a selective vacuum coupler and/or by a selective electromagnetic coupler, etc.) to secure the substrate to the vacuum chuck. In some embodiments, the one or more clamps are to align the substrate on the vacuum chuck (e.g., in an XY plane).

At block 550, one or more sealing members are compressed within a groove of the vacuum chuck. In some embodiments, the downward force provided by the substrate flattening unit causes the one or more sealing members to be compressed. Compression of the one or more sealing members may aid in forming the vacuum seal between the substrate and the vacuum chuck. In some embodiments, the one or more sealing members are an o-ring seal, a lip seal, or a gasket seal.

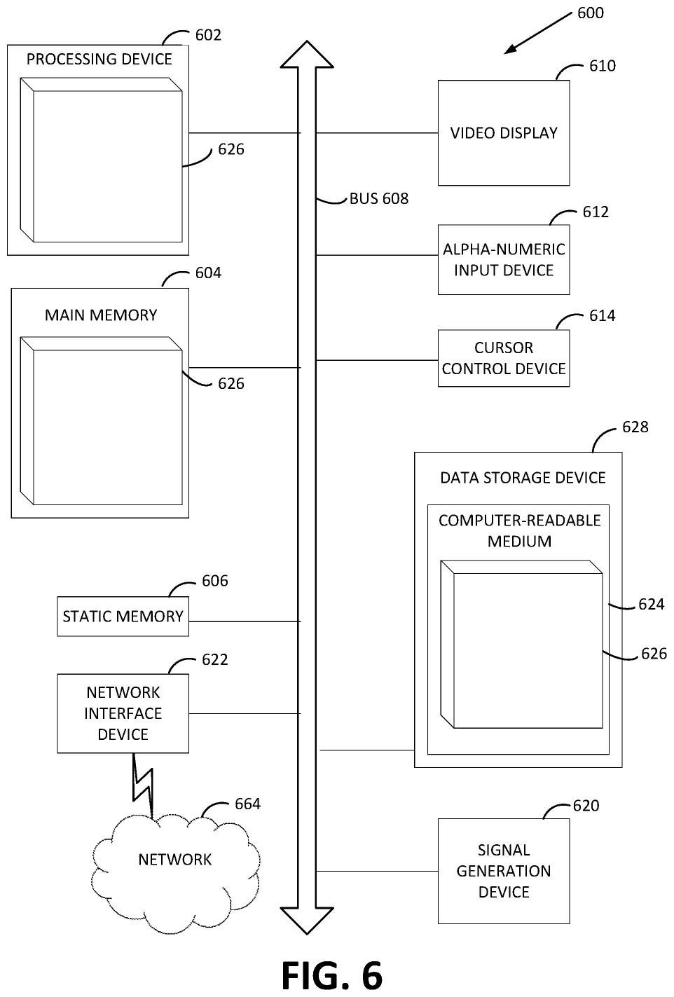

FIG. 6 illustrates a block diagram of an example computer system 600 in accordance with at least one embodiment of the present disclosure. In alternative embodiments, the computer system 600 can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 600 can correspond to one or more of controllers 280, 380, 480 as described herein.

The example computing system 600 includes a processing device 602, a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 628), which communicate with each other via a bus 608.

Processing device 602 can represent one or more general-purpose processors such as a microprocessor, central processing unit, or the like. More particularly, the processing device 602 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. Processing device 602 can also be or include a system on a chip (SoC), programmable logic controller (PLC), or other type of processing device. Processing device 602 is configured to execute the processing logic for performing operations discussed herein.

The computing device 600 can further include a network interface device 622 for communicating with a network 664. The computing device 600 also can include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 620 (e.g., a speaker).

The data storage device 628 can include a machine-readable storage medium (or more specifically a non-transitory machine-readable storage medium) 624 on which is stored one or more sets of instructions 626 embodying any one or more of the methodologies or functions described herein. A non-transitory storage medium refers to a storage medium other than a carrier wave. The instructions 626 can also reside, completely or at least partially, within the main memory 604 and/or within the processing device 602 during execution thereof by the computer device 600, the main memory 604 and the processing device 602 also constituting computer-readable storage media.

While the computer-readable storage medium 624 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a vacuum chuck configured to secure a substrate;
a substrate flattening unit configured to apply a downward force to a top surface of the substrate to flatten the substrate on the vacuum chuck; and
one or more sealing members configured to form a vacuum seal between the vacuum chuck and the substrate proximate to one or more peripheral edges of the substrate when the substrate is flattened by the substrate flattening unit.

2. The system of claim 1, wherein the one or more sealing members comprises one or more clamps configured to hold the substrate proximate to the one or more peripheral edges of the substrate.

3. The system of claim 2, wherein the substrate flattening unit is configured to deploy the one or more clamps to the vacuum chuck to flatten the substrate on the vacuum chuck.

4. The system of claim 3, wherein the one or more clamps are configured to removably couple to the substrate flattening unit for deployment to the vacuum chuck.

5. The system of claim 1, wherein the one or more sealing members comprise at least one of an o-ring seal, a lip seal, or a gasket seal.

6. The system of claim 1, wherein the vacuum chuck comprises a groove to hold the one or more sealing members, and wherein the one or more sealing members is to compress within the groove responsive to a flattening force applied by the substrate flattening unit.

7. The system of claim 1, wherein the vacuum chuck is configured to retain the substrate in a flattened state responsive to flattening of the substrate by the substrate flattening unit.

8. The system of claim 1, further comprising:
a movable stage, wherein the vacuum chuck is to secure the substrate to the movable stage.

9. A system, comprising:
a vacuum chuck configured to secure a substrate; and
one or more clamps deployable to the vacuum chuck and configured to hold the substrate proximate to one or more peripheral edges of the substrate to secure the substrate to the vacuum chuck.

10. The system of claim 9, wherein the one or more clamps are configured to be deployed to the vacuum chuck by a substrate flattening unit.

11. The system of claim 10, wherein the one or more clamps are to couple to the substrate flattening unit for deployment to the vacuum chuck.

12. The system of claim 11, wherein the one or more clamps are to couple to the substrate flattening unit by one of a selective vacuum coupler or a selective electromagnetic coupler.

13. The system of claim 9, wherein the one or more clamps are configured to removably couple to the vacuum chuck.

14. The system of claim 9, wherein the one or more clamps are configured to actuate to flatten the substrate on the vacuum chuck.

15. A method, comprising:
receiving a substrate on a vacuum chuck; and
flattening, by a substrate flattening unit, the substrate on the vacuum chuck, wherein a vacuum seal is formed between the vacuum chuck and the substrate by one or more sealing members responsive to the flattening.

16. The method of claim 15, wherein the flattening comprises:
applying, by the substrate flattening unit, a downward force to a top surface of the substrate to flatten the substrate on the vacuum chuck.

17. The method of claim 15, further comprising:
deploying, by the substrate flattening unit, one or more clamps to the vacuum chuck to flatten the substrate on the vacuum chuck.

18. The method of claim 17, wherein the one or more clamps are configured to removably couple to the substrate flattening unit by one of a selective vacuum coupler or a selective electromagnetic coupler.

19. The method of claim 15, further comprising:
compressing the one or more sealing members within a groove of the vacuum chuck.

20. The method of claim 19, wherein the one or more sealing members comprise at least one of an o-ring seal, a lip seal, or a gasket seal.
